(19) United States
(12) Patent Application Publication
(10) Pub. No.: US 2025/0285845 A1
(43) Pub. Date: Sep. 11, 2025

(54) LIFTING APPARATUS MOUNTED IN SUBSTRATE DEPOSITION

(71) Applicant: INNO ROBOTICS INC., Hwaseong-si (KR)

(72) Inventors: Kyu Jung CHO, Hwaseong-si (KR); Minji KIM, Suwon-si (KR)

(73) Assignee: INNO ROBOTICS INC., Hwaseong-si (KR)

(21) Appl. No.: 18/931,767

(22) Filed: Oct. 30, 2024

(30) Foreign Application Priority Data
Mar. 5, 2024 (KR) 10-2024-0031492

(51) Int. Cl. H01J 37/32; C23C 16/458; C23C 16/46; H01L 21/687

(52) U.S. Cl. CPC H01J 37/32724; C23C 16/4583; C23C 16/463; H01L 21/68742; H01J 37/321; H01J 2237/002; H01J 2237/3321

(57) ABSTRACT

Provided is a lifting device mounted to a substrate deposition equipment, the lifting device including a gantry-type base including a top plate and a pair of side plates and having a space formed inside; a guide track formed on each of the pair of side plates that faces each other; a guide unit configured to move upward or downward along the guide track; a linker formed in an internal space of the base and configured to connect to the guide unit; a level regulator attached to the linker; a top cooling plate attached to the top of the level regulator; a ceramic shaft configured to guide the rise and fall of a ceramic plate at the center of the top cooling plate; and a lifting shaft configured to insert into the inside of the ceramic shaft and to connect to a susceptor.

### CROSS-REFERENCE TO RELATED APPLICATION(S)

This application claims the benefit under 35 USC § 119(a) of Korean Patent Application No. 10-2024-0031492 filed on Mar. 5, 2024 in the Korean Intellectual Property Office, the entire disclosure of which is incorporated herein by reference for all purposes.

### BACKGROUND

### 1. Field

The present invention relates to a lifting device mounted to a substrate deposition equipment, and more particularly, to a device mounted to a chemical vapor deposition (CVD) facility to raise and lower a substrate.

The present invention is research supported by research funds from the Ministry of Trade, Industry and Energy and the Korea Institute for Industrial Technology Planning and Evaluation (KEIT) in 2024 (Project No. 20019103).

### 2. Related Art

Chemical vapor deposition (CVD) technology refers to technology that applies energy to gas containing chemical substances through heat or light and turns the same into plasma at high frequency to increase reactivity of raw material to be adsorbed on a substrate.

A chemical vapor deposition method may achieve excellent film quality and fast film stacking speed and may acquire the desired chemical composition of a thin film through chemical reaction. In a display process, the chemical vapor deposition method may be used to stack a-Si or to stack a thin film transistor (TFT) insulating film (e.g., gate insulator, inter-layer deposition) and a protective layer (e.g., passivation) in a liquid crystal display (LCD) and an organic light emitting diode (OLED).

Among various chemical vapor deposition methods, inductively coupled plasma (ICP) CVD is a method that floats plasm to make electrons continuously move in the space above a chamber and uses gravity to make the plasma come down. In the case of ICP, the travel distance of electrons increases (rotating electrons in magnetic field), which increases the probability of collision between gases and electrons. Therefore, the ICP may form high-density plasma at low pressure.

In ICP CVD, the temperature of an evaporator source is high at 450° C. and high temperature is generated within the chamber even in the electron rotation process.

In a general CVD process, it is important to prevent heat from being transferred to a susceptor on which a substrate is placed in a chamber and to a lifting device that supports the same. Also, in the case of a general lifting device used in the industrial field, a motor that is a power source for raising and lowering is not placed at the center of the device, but is installed on one side due to a complex structure and the eccentric control of the motor is required accordingly. However, distortion of a raising and lowering part caused by the power source being eccentric rather than centered is a problem in a deposition process that requires precise control.

### SUMMARY

An objective of the present invention is to provide a lifting device mounted to a substrate deposition equipment in a structure that prevents a power source for raising and lowering from being eccentric.

Also, an objective of the present invention is to provide a lifting device that minimizes deformation due to heat generated in a connected chamber.

A lifting device according to an example embodiment refers to a lifting device mounted to a substrate deposition equipment, and includes a gantry-type base including a top plate and a pair of side plates and having a space formed inside; a guide track formed on each of the pair of side plates that faces each other; a guide unit configured to move upward or downward along the guide track; a linker formed in an internal space of the base and configured to connect to the guide unit; a level regulator attached to the linker; a top cooling plate attached to the top of the level regulator; a ceramic shaft configured to guide the rise and fall of a ceramic plate at the center of the top cooling plate; and a lifting shaft configured to insert into the inside of the ceramic shaft and to connect to a susceptor.

The lifting device according to an example embodiment further includes a buffer member configured to surround the ceramic shaft at the bottom of the top cooling plate; and a bottom cooling plate configured to couple to one end of the ceramic shaft at the bottom the buffer member, and a cooling channel is included in the top cooling plate and the bottom cooling plate.

As an example embodiment, the ceramic shaft is inserted at the center of the top cooling plate and the bottom cooling plate, a first area in which a buffer member is fastened is formed in a cylindrical shape, and a second area that is above the top cooling plate is formed in a polygonal column shape.

As an example embodiment, the lifting device according to an example embodiment further includes a bracket attached to the top of the top cooling plate and formed to contact the surface of the ceramic shaft in the polygonal column shape.

As an example embodiment, a graphite plate attached to a partial top area of the top plate is included.

As an example embodiment, a cross roller hinge is attached to the bottom of the level regulator.

As an example embodiment, the lifting device according to an example embodiment further includes a reinforcement member configured to connect the pair of side plates.

According to a lifting device mounted to a substrate deposition equipment according to an example embodiment, the probability of errors occurring in substrate alignment within a chamber may be reduced.

Also, despite deformation of mechanism due to heat, errors of substrate alignment may not occur in the chamber.

The additional scope of applicability of the present invention will become apparent from the detailed description set forth herein. However, since various modifications and alterations within the spirit and scope of the present invention may be clearly understood by one of ordinary skill in the art, the detailed description and specific example embodiments such as preferred example embodiments should be understood as being given as examples only.

### BRIEF DESCRIPTION OF THE DRAWINGS

These and/or other aspects, features, and advantages of the disclosure will become apparent and more readily appreciated from the following description of example embodiments, taken in conjunction with the accompanying drawings of which:

FIG. 1 is a cross-sectional view of a lifting device according to an example embodiment;

FIGS. 2 and 3 are enlarged perspective views of a lifting device according to an example embodiment; and

FIG. 4 shows measurement results of the degree of deformation and stress due to heat of a base according to an example embodiment.

### DETAILED DESCRIPTION

The specific structural or functional descriptions of example embodiments according to the concept of the present invention disclosed herein are merely intended for the purpose of describing the example embodiments according to the concept of the present invention and the example embodiments according to the concept of the present invention may be implemented in various forms and are not construed as limited to the example embodiments described herein.

Although terms of “first,” “second,” and the like are used to explain various components, the components are not limited to such terms. These terms are used only to distinguish one component from another component. For example, a first component may be referred to as a second component, or similarly, the second component may be referred to as the first component without departing from the scope according to the concept of the present invention.

When it is mentioned that one component is “connected” or “accessed” to another component, it may be understood that the one component is directly connected or accessed to another component or that still other component is interposed between the two components. In addition, when it is described that one component is “directly connected” or “directly accessed” to another component, it should be understood that still other component is absent therebetween. Likewise, expressions describing relationships between components, for example, “between” and “immediately between” and “immediately adjacent to” may also be construed as described in the foregoing.

The terminology used herein is for the purpose of describing particular example embodiments only and is not to be limiting of the present invention. As used herein, the singular forms “a,” “an,” and “the” are intended to include the plural forms as well, unless the context clearly indicates otherwise. It will be further understood that the terms “comprises/includes” or “has,” when used in this specification, specify the presence of stated features, integers, stages, operations, components, parts, or combinations thereof, but do not preclude the presence or addition of one or more other features, integers, stages, operations, components, parts, or combinations thereof.

Hereinafter, example embodiments will be described in detail with reference to the accompanying drawings.

The present invention relates to a “Z module for 8.6 G inductively coupled plasma (ICP) deposition equipment” and, for clarity of description, is referred to as a lifting device mounted to a substrate deposition equipment, which is the name of the present invention.

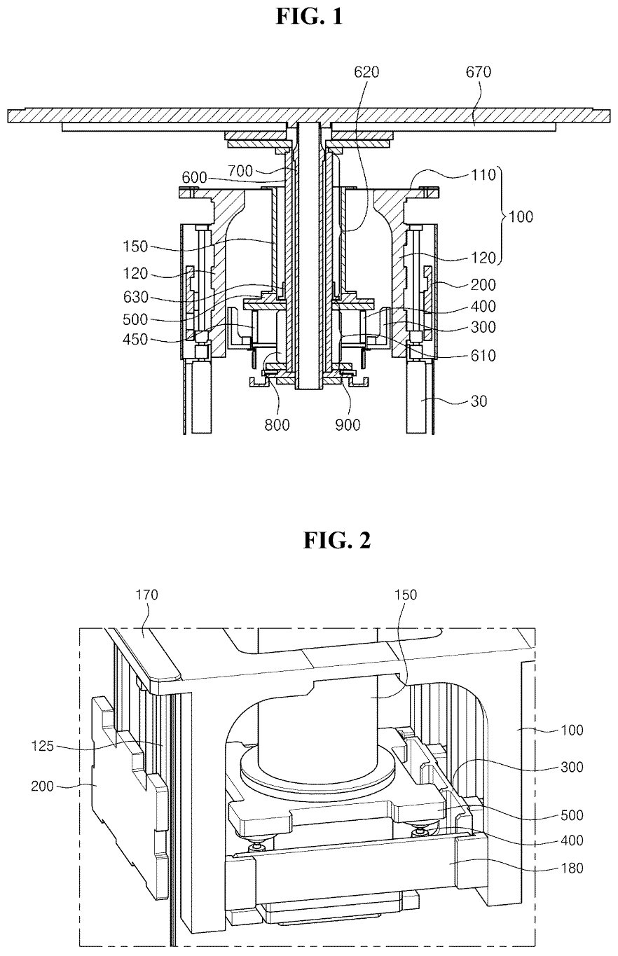

FIG. 1 is a cross-sectional view of a lifting device according to an example embodiment.

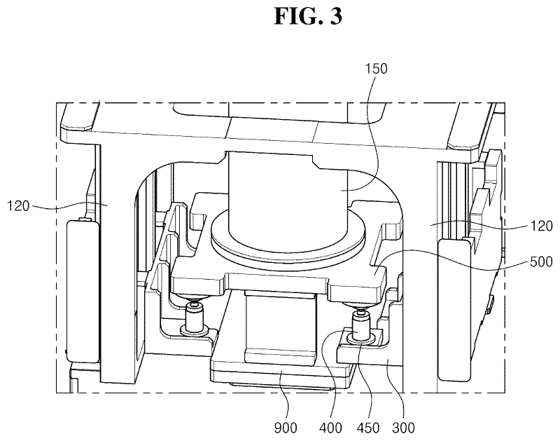

FIGS. 2 and 3 are enlarged perspective views of a lifting device according to an example embodiment.

As shown in FIGS. 1, 2, and 3, the lifting device according to an example embodiment refers to a lifting device mounted to a substrate deposition equipment, and includes a gantry-type base 100 including a top plate 110 and a pair of side plates 120 and having a space formed inside, a guide track 125 formed on each of the pair of side plates 120 that faces each other, a guide unit 200 configured to move upward or downward along the guide track 125, a linker 300 formed in an internal space of the base 100 and configured to connect to the guide unit 200, a level regulator 400 attached to the linker 300, a top cooling plate 500 attached to the top of the level regulator 400, a ceramic shaft 600 configured to guide the rise and fall of a ceramic plate 670 at the center of the top cooling plate 500, and a lifting shaft 700 configured to insert into the ceramic shaft 600 and to connect to a susceptor.

The lifting device mounted to the substrate deposition equipment according to an example embodiment relates to a device mounted to chemical vapor deposition facility to raise and lower a substrate and is to improve the structural limitation of the conventional device.

The lifting device according to an example embodiment includes the gantry-type base 100. The gantry-type base 100 includes the top plate 110 and the pair of side plates 120 configured to couple to the top plate 110 on its both sides. The base 100 corresponds to a metal structure made of a steel material. The top plate 110 and the pair of side plates 120 may be integrally formed or may be the assembly of separate component parts.

As shown in FIGS. 1 and 2, a graphite plate 170 is attached on the top surface of the base top plate 110. The graphite plate 170 prevents or delays heat in a chamber from being radiated and transferred to the base 100.

Also, although expression of the side plate 120 is used in the lifting device according to an example embodiment, any structure capable of supporting the top plate 110, such as a desk, may be applied.

The guide track 125 is formed on each of the pair of side plates 120 constituting the base 100 according to an example embodiment. The guide track 125 formed in a vertical direction is formed in a symmetrical shape and size relative to each of the side plates 120 and the guide unit 200, described below, is fastened to the guide track 125.

The guide track 125 may be formed of two tracks as shown in FIG. 2, but is not necessarily limited thereto.

The guide unit 200 moves upward or downward along the aforementioned guide track 125. As shown in FIG. 2, the guide unit 200 is connected to the outside of the single pair of side plates 120 constituting the base 100 and moves upward or downward.

The guide unit 200 may be made of a metal material with guaranteed durability and it is desirable that no deformation occurs due to temperature.

In particular, the guide unit 200 installed on each of the single pair of side plates 120 has the same size and weight and is fastened to the guide track 125.

As shown in FIGS. 2 and 3, the linker 300 according to an example embodiment is formed in the inner space of the base 100 and is connected to the guide unit 200.

In more detail, the linker 300 is formed in the internal space formed by the top plate 110 and the single pair of side plates 120 of the base 100 and is connected to the guide unit 200 through the guide track 125.

The linker 300 is a metal structure with an “L” shaped cross section. The linker 300 is symmetrically installed in each of the single pair of side plates 120 and connected to the guide unit 200.

The level regulator 400 is attached to the top of the linker 300. As shown in FIGS. 2 and 3, one end of the disk-shaped level regulator 400 is installed at each of four top corners of the linker 300. The other end of the level regulator 400 is connected to each of corners of the top cooling plate 500, which will be described below.

The level regulator 400 prevents the ceramic shaft 600 and the lifting shaft 700 shown in FIG. 1 from tilting when moving upward or downward, and ultimately allows the ceramic plate 670 to which the ceramic shaft 600 is connected to maintain equilibrium. This ensures that the susceptor accommodated in the ceramic plate 670 maintains equilibrium, and ultimately, allows the substrate, which is a deposition object, to maintain equilibrium during an ICP CVD process.

The top cooling plate 500 is attached to the top of the level regulator 400 and rises and falls along movement of the linker 300. A cooling channel (not shown) is built inside the top cooling plate 500 and serves to prevent heat generated by coolant flow from being transferred to the base 100.

The top cooling plate 500 has a hole at the center through which the ceramic shaft 600 may move. As shown in FIGS. 2 and 3, a cylindrical bellows 150 with open top surface and bottom surface is fastened to the ceramic shaft 600.

The top cooling plate 500 may be assembled by bolting two plates together and may also be formed in an integrated structure in which a manifold cooling channel is formed.

The ceramic shaft 600 is inserted and fastened inside the bellows 150 fastened to the top of the top cooling plate 500, and the lifting shaft 700 configured to move the susceptor is inserted and fastened inside the ceramic shaft 600.

The ceramic shaft 600 guides the rise and fall of the ceramic plate 670 at the center of the top cooling plate 500. The ceramic material has low thermal conductivity, so prevents heat, which is generated in the chamber and transferred to the lifting shaft 700 along the susceptor, from being transferred to other components including the base 100.

As shown in FIG. 1, the ceramic shaft 600 is inserted at the center of the top cooling plate 500 and a bottom cooling plate 900, and is divided into a first area (610) in which a buffer member 800 is fastened and a second area (620) that is above the top cooling plate 500.

In general, the ceramic shaft 600 is configured in a cylindrical shape for convenience of processing and the ceramic shaft 600 rotates due to internal and external factors as the rise and fall is repeated, which causes the ceramic plate 670 and the susceptor to rotate and the substrate to be misaligned. Therefore, as for the ceramic shaft 600 according to an example embodiment, the first area (610) is processed into a cylindrical shape and the second area (620) is configured in a polygonal column shape with a polygonal cross section.

Also, the lifting device according to an example embodiment further includes a bracket 630 attached on the top surface of the top cooling plate 500 to contact one surface of the polygonal column shape.

The bracket 630 includes an “L” shaped bent metal piece, and at least one bracket 630 is attached on the top surface of the top cooling plate 500 to prevent rotation of the ceramic shaft 600.

A cylindrical hole is formed inside the ceramic shaft 600 and the lifting shaft 700 is inserted into the hole in a longitudinal direction. The lifting shaft 700 is configured to pass through the ceramic plate 670 and to directly connect to the susceptor (not shown), and is made of a metal material with guaranteed rigidity and heat resistance.

The lifting device according to an example embodiment includes the buffer member 800 configured to surround the ceramic shaft 600 coupled at the bottom of the top cooling plate 500. The buffer member 800 is desirably made of Teflon. Teflon has a high melting point and excellent heat resistance and chemical resistance, so prevents rotation of the ceramic shaft 600 and also prevents surrounding equipment from being affected or deformed by impact from internal and external factors.

The buffer member 800 formed below the top cooling plate 500 is surrounded by a protecting cover made of a metal material and the bottom cooling plate 900 is coupled at the bottom of the buffer member 800.

As shown in FIGS. 1 and 3, the bottom cooling plate 900 is joined at one end of the ceramic shaft 600.

Also, according to an example embodiment, the lower side of the lifting shaft 700 may be installed to contact the bottom cooling plate 900. Like the top cooling plate 500, a cooling channel (not shown) is installed in the bottom cooling plate 900. The heat transferred through the lifting shaft 700 is cooled through the bottom cooling plate 900 and is prevented from being transferred to the base 100.

A cross roller hinge 450 is attached to the bottom of the level regulator 400 according to an example embodiment. The level regulator 400 compensates for tilting of the ceramic plate 600 and the susceptor, and the cross roller hinge 450 responds to lateral deformation of the base 100 that may occur due to heat or other external factors.

As shown in FIG. 1, the cross roller hinge 450 includes a cross roller guide (not shown) installed in a side longitudinal direction and a spherical bearing (not shown) therein, so the spherical bearing moves along the cross roller guide due to lateral deformation and compensation for the deformation is performed.

The lifting device according to an example embodiment further includes a reinforcement member 180 configured to connect the pair of side plates 120. As shown in FIG. 2, the reinforcement member 180 is attached to connect one corner of the side plate 120. The reinforcement member 180 may be integrally configured with the base 100, but for ease of maintenance and device assembly, it is desirable to assemble the reinforcement member 180 with bolts and the like, separate from the base 100.

As shown in FIG. 2, the reinforcement member 180 is made of a metal alloy and may be the same material as that of the base 100, but is desirably made of a metal material with lower thermal strain than the base 100.

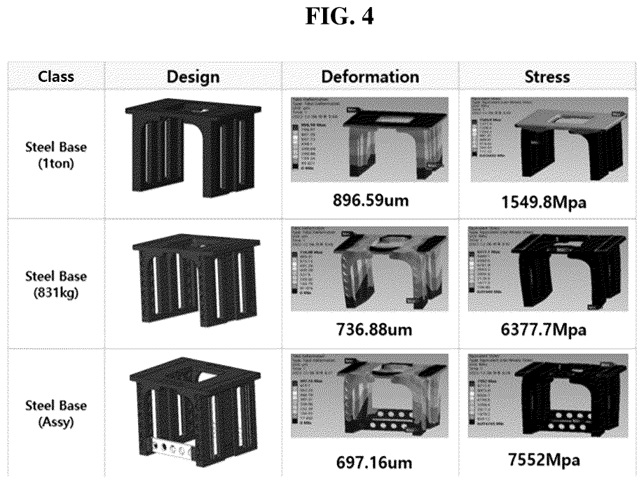

FIG. 4 shows measurement results of the degree of deformation and stress due to heat of a base according to an example embodiment.

The existing steel base weighs close to 1 ton and has thermal deformation of 896.59 μm and shear stress of 1549.8 Mpa, and the weight-reduced base 100 according to an example embodiment is a steel base, but weighs 831 kg, which is reduced in weight compared to the existing steel base, and has thermal deformation of 736.88 μm and shear stress of 6377.7 Mpa. Also, a steel base in which the reinforcement member 180 is fastened to the weight-reduced base 100 according to another example embodiment shows improvement with thermal deformation of 697.16 μm and shear stress of 7552 Mpa.

The lifting device according to an example embodiment improves the strain and the shear stress caused by heat by reducing the weight of the base 100 made of a steel material and further improves lightness and secure rigidity by additionally installing the reinforcement member 180 on the base 100 made of a steel material.

In particular, the lifting device according to an example embodiment minimizes the heat transferred to the base 100 and minimizes deformation of the base 100 due to heat transfer by installing the top cooling plate 500, the bottom cooling plate 900, the graphite plate 170, and the like. Also, structurally, instead of the rise and fall by eccentric control of a motor 30 as in the art, two motors 30 installed on both sides of the gantry-type base 100, respectively, may provide rotational force on both sides to concentrically control the ceramic shaft 600 and the lifting shaft 700 that are provided in the center.

Also, the lifting device according to an example embodiment divides the ceramic shaft 600 into an area with a cylindrical shape and an area with a polygonal column shape to prevent the ceramic shaft 600 from rotating when moving upward or downward, and maintains balance of the susceptor by way of the level regulator 400.

Various modifications may be made to the example embodiments according to the concept of the present invention and thus, specific example embodiments are illustrated in the drawings and described in detail through the present specification. However, it should be understood that the example embodiments according to the concept of the present invention are not construed as limited to specific implementations and should be understood to include all changes, equivalents, and replacements within the idea and the technical scope of the present invention.

What is claimed is:

1. A lifting device mounted to a substrate deposition equipment, the lifting device comprising:
a gantry-type base including a top plate and a pair of side plates and having a space formed inside;
a guide track formed on each of the pair of side plates that faces each other;
a guide unit configured to move upward or downward along the guide track;
a linker formed in an internal space of the base and configured to connect to the guide unit;
a level regulator attached to the linker;
a top cooling plate attached to the top of the level regulator;
a ceramic shaft configured to guide the rise and fall of a ceramic plate at the center of the top cooling plate; and
a lifting shaft configured to insert into the inside of the ceramic shaft and to connect to a susceptor.

2. The lifting device of claim 1, further comprising:
a buffer member configured to surround the ceramic shaft at the bottom of the top cooling plate; and
a bottom cooling plate configured to couple to one end of the ceramic shaft at the bottom of the buffer member,
wherein a cooling channel is included in the top cooling plate and the bottom cooling plate.

3. The lifting device of claim 1, wherein the ceramic shaft is inserted at the center of the top cooling plate and the bottom cooling plate, a first area in which a buffer member is fastened is formed in a cylindrical shape, and a second area that is above the top cooling plate is formed in a polygonal column shape.

4. The lifting device of claim 3, further comprising:
a bracket attached to the top of the top cooling plate and formed to contact the surface of the ceramic shaft in the polygonal column shape.

5. The lifting device of claim 1, wherein a graphite plate attached to a partial top area of the top plate is included.

6. The lifting device of claim 1, wherein a cross roller hinge is attached to the bottom of the level regulator.

7. The lifting device of claim 1, further comprising:
a reinforcement member configured to connect the pair of side plates.
